(19) United States
(12) Patent Application Publication
(10) Pub. No.: US 2026/0081598 A1
(43) Pub. Date: Mar. 19, 2026

(54) VOLTAGE GENERATION CIRCUIT, GATE DRIVER, AND SEMICONDUCTOR MODULE

(71) Applicant: KABUSHIKI KAISHA TOSHIBA, Tokyo (JP)

(72) Inventors: Tomoaki INOKUCHI, Yokohama Kanagawa (JP); Shotaro BABA, Kawasaki Kanagawa (JP); Hiroki NEMOTO, Meguro Tokyo (JP); Hiro GANGI, Marugame Kagawa (JP); Yusuke KOBAYASHI, Yokohama Kanagawa (JP); Taichi FUKUDA, Yokohama Kanagawa (JP); Tatsunori SAKANO, Shinagawa Tokyo (JP); Yosuke KAJIWARA, Yokohama Kanagawa (JP)

(73) Assignee: KABUSHIKI KAISHA TOSHIBA, Tokyo (JP)

(21) Appl. No.: 19/248,627

(22) Filed: Jun. 25, 2025

(30) Foreign Application Priority Data
Sep. 13, 2024 (JP) 2024-159322

(51) Int. Cl. H03K 17/567; H10D 64/00; H10D 64/23; H10D 64/27; H10D 64/64

(52) U.S. Cl. CPC H03K 17/567; H10D 64/112; H10D 64/117; H10D 64/256; H10D 64/513; H10D 64/516; H10D 64/647

(57) ABSTRACT

A voltage generation circuit includes a first terminal; a second terminal; a field-effect transistor of a depletion type; a first diode connected between the first terminal and the field-effect transistor; and a first capacitor connected between the field-effect transistor and ground. An anode terminal of the first diode is connected to the first terminal. A cathode terminal of the first diode is connected to a drain terminal of the field-effect transistor. A source terminal of the field-effect transistor is connected to the second terminal and one end of the first capacitor. A gate terminal of the field-effect transistor is connected to another end of the first capacitor.

### CROSS-REFERENCE TO RELATED APPLICATIONS

This application is based upon and claims the benefit of priority from Japanese Patent Application No.2024-159322, filed on Sep. 13, 2024; the entire contents of which are incorporated herein by reference.

### FIELD

Embodiments described herein relate generally to a voltage generation circuit, a gate driver, and a semiconductor module.

### BACKGROUND

For example, a semiconductor switching element, such as a power device, is turned on and off by a gate control signal from a gate drive circuit.

### BRIEF DESCRIPTION OF THE DRAWINGS

FIG. 1 is a circuit diagram of a semiconductor module of an embodiment;

FIG. 2A and FIG. 2B are circuit diagrams of a voltage generation circuit of a first embodiment;

FIG. 3A is a waveform diagram of an input voltage Vin of the voltage generation circuit, and FIG. 3B is a waveform diagram of an output voltage Vout of the voltage generation circuit;

FIG. 4 is a circuit diagram of a voltage generation circuit of a second embodiment;

FIG. 5A and FIG. 5B are circuit diagrams of a voltage generation circuit of a third embodiment;

FIG. 6A is a waveform diagram of a source potential V_{C1} of a field-effect transistor M1 in the voltage generation circuit of the third embodiment, and FIG. 6B is a waveform diagram of a gate potential Vg of the field-effect transistor M1 changing in response to a change in the potential V_{C1} in FIG. 6A;

FIG. 7A to FIG. 7C are circuit diagrams of a voltage generation circuit of a fourth embodiment;

FIG. 8 is a schematic cross-sectional view of an example of the field-effect transistor in the voltage generation circuits of the embodiments;

FIG. 9 is a schematic cross-sectional view of a semiconductor device of an embodiment;

FIG. 10 and FIG. 11 are schematic perspective views of the semiconductor device of the embodiment;

FIG. 12 is a schematic cross-sectional view of the semiconductor device of the embodiment;

FIG. 13A and FIG. 13B are schematic perspective views of the semiconductor device of the embodiment;

FIG. 14 is a schematic perspective view of the semiconductor device of the embodiment; and

FIG. 15 is a schematic cross-sectional view of the semiconductor device of the embodiment.

### DETAILED DESCRIPTION

According to one embodiment, a voltage generation circuit includes a first terminal, a second terminal, a field-effect transistor of a depletion type, a first diode connected between the first terminal and the field-effect transistor, and a first capacitor connected between the field-effect transistor and ground, an anode terminal of the first diode is connected to the first terminal, a cathode terminal of the first diode is connected to a drain terminal of the field-effect transistor, a source terminal of the field-effect transistor is connected to the second terminal and one end of the first capacitor, and a gate terminal of the field-effect transistor is connected to another end of the first capacitor.

Embodiments will now be described with reference to the drawings.

The drawings are schematic or conceptual, and the relationship between the thickness and width of each portion, the proportions of sizes among portions, and so on are not necessarily the same as the actual values. Even the dimensions and proportion of the same portion may be illustrated differently depending on the drawing. The same or similar elements are denoted by the same reference numerals. In the explanation of the circuit diagrams, “connected” means “electrically connected”.

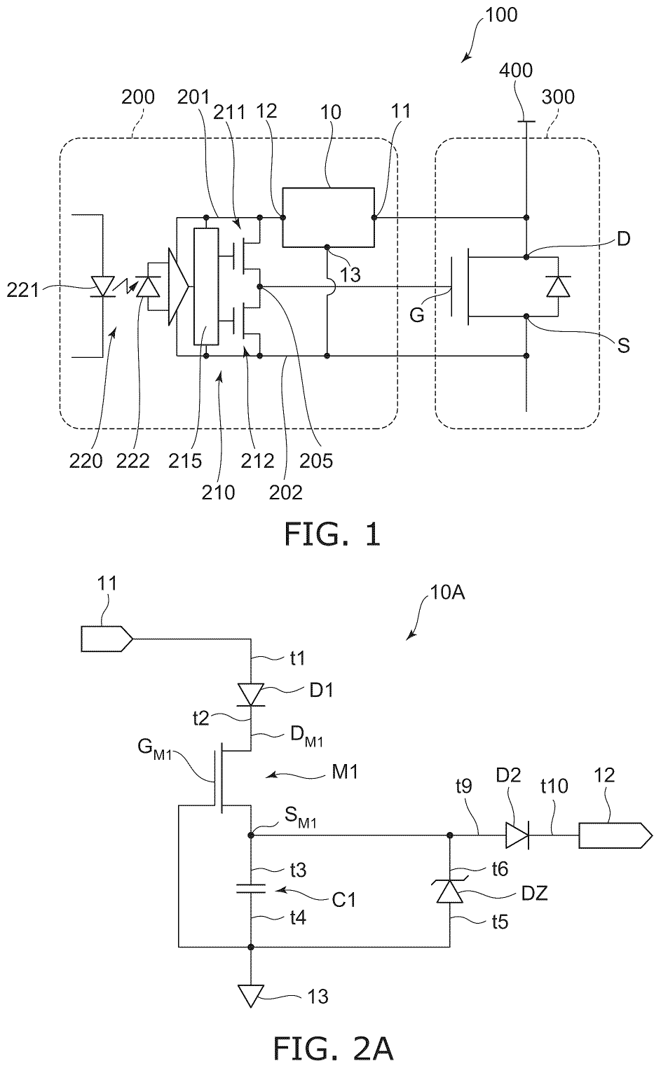

FIG. 1 is a circuit diagram of a semiconductor module 100 of an embodiment. The semiconductor module 100 includes a gate driver 200 and a semiconductor switching element 300. The gate driver 200 and the semiconductor switching element 300 are separate package components. Alternatively, the gate driver 200 and the semiconductor switching element 300 are built into one package.

The semiconductor switching element 300 is a power device for power control and is, for example, a field-effect transistor (MOSFET: Metal-Oxide-Semiconductor Field-Effect Transistor). Alternatively, the semiconductor switching element 300 may be an insulated gate bipolar transistor (IGBT).

The semiconductor switching element 300 is, for example, an n-type MOSFET, and a drain terminal D of the semiconductor switching element 300 is connected to a power supply line 400. The semiconductor switching element 300 is, for example, a high-side element in a power conversion circuit in which the high-side element and a low-side element are connected in series between the power supply line 400 and ground. A source terminal S of the semiconductor switching element 300 is connected to the drain terminal of the low-side element. The source terminal of the low-side element is connected to the ground. The source terminal S of the semiconductor switching element 300 is connected to the ground via the low-side element. When the semiconductor switching element 300 is an IGBT, the drain terminal can be replaced with a collector terminal, and the source terminal can be replaced with an emitter terminal.

Note that the gate driver 200 of the embodiment can also be used as a gate driver for the low-side element.

The gate driver 200 includes a gate drive circuit 210, a voltage generation circuit 10, and a photocoupler 220. The gate drive circuit 210 includes a first semiconductor element 211, a second semiconductor element 212, and a control circuit 215.

The first semiconductor element 211 and the second semiconductor element 212 are, for example, n-type MOSFETs. The drain terminal of the first semiconductor element 211 is connected to a voltage input line 201 of the gate drive circuit 210. The voltage input line 201 of the gate drive circuit 210 is connected to the voltage generation circuit 10. The source terminal of the first semiconductor element 211 is connected to the drain terminal of the second semiconductor element 212. The source terminal of the first semiconductor element 211 and the drain terminal of the second semiconductor element 212 are connected to an output terminal 205 of the gate drive circuit 210. The output terminal 205 of the gate drive circuit 210 is connected to a gate terminal G of the semiconductor switching element 300. The source terminal of the second semiconductor element 212 is connected to a reference potential line 202 of the gate drive circuit 210. The reference potential line 202 of the gate drive circuit 210 is connected to the source terminal S of the semiconductor switching element 300.

The control circuit 215 is connected between the voltage input line 201 and the reference potential line 202 of the gate drive circuit 210. The gate terminal of the first semiconductor element 211 and the gate terminal of the second semiconductor element 212 are connected to the control circuit 215.

The photocoupler 220 includes a light emitting element 221 and a light receiving element 222. The light emitting element 221 outputs, as an optical signal, a gate control signal input from an external circuit as an electric signal. The light receiving element 222 is connected between the voltage input line 201 and the reference potential line 202 of the gate drive circuit 210. The light receiving element 222 receives the optical signal emitted by the light emitting element 221, converts the optical signal into an electric signal, and outputs the electric signal to the control circuit 215. The control circuit 215 controls the potential of the gate terminal of the first semiconductor element 211 and the potential of the gate terminal of the second semiconductor element 212 based on the gate control signal input from the light receiving element 222. The control circuit 215 alternately turns on and off the first semiconductor element 211 and the second semiconductor element 212.

The voltage generation circuit 10 supplies a DC voltage to the voltage input line 201 of the gate drive circuit 210. Since the first semiconductor element 211 and the second semiconductor element 212 are alternately turned on and off, a pulse voltage is output to the output terminal 205 of the gate drive circuit 210. This pulse voltage is supplied to the gate terminal G of the semiconductor switching element 300, and the semiconductor switching element 300 is turned on and off.

A specific example of the voltage generation circuit 10 will be described below. As the voltage generation circuit 10 shown in FIG. 1, a voltage generation circuit having a configuration of any one of voltage generation circuits 10A to 10D of embodiments described below or a combination of two or more thereof can be used.

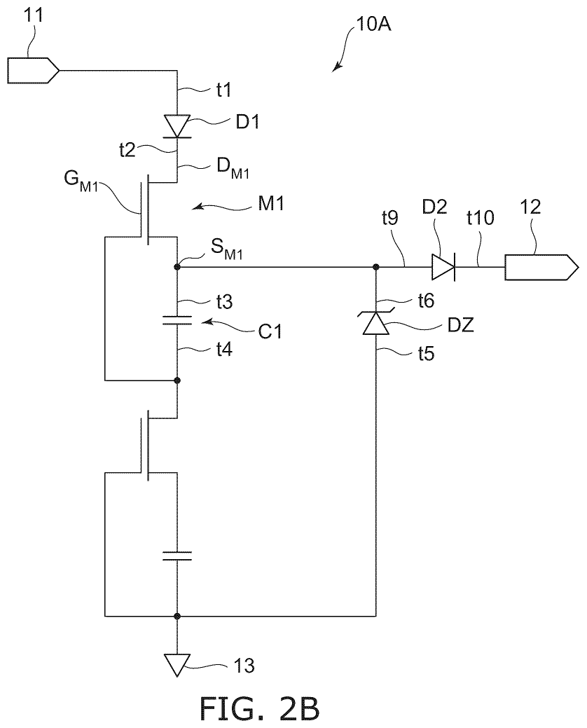

FIG. 2A is a circuit diagram of the voltage generation circuit 10A of a first embodiment. The voltage generation circuit 10A of the first embodiment includes a first terminal 11, a second terminal 12, a field-effect transistor M1, a first diode D1, and a first capacitor C1. Further, the voltage generation circuit 10A includes, for example, a ground terminal 13.

The first terminal 11 is a voltage input terminal and is connected to the drain terminal D of the semiconductor switching element 300 shown in FIG. 1. The second terminal 12 is a voltage output terminal and is connected to the voltage input line 201 of the gate drive circuit 210 shown in FIG. 1. The first diode D1, the field-effect transistor M1, and the first capacitor C1 are connected in series between the first terminal 11 and the ground.

The field-effect transistor M1 is a field-effect transistor of the depletion type and has a negative threshold voltage (−Vth). The field-effect transistor M1 is, for example, an n-type MOSFET.

The first diode D1 is connected between the first terminal 11 and the field-effect transistor M1. An anode terminal t1 of the first diode D1 is connected to the first terminal 11, and a cathode terminal t2 of the first diode D1 is connected to a drain terminal D_{M1} of the field-effect transistor M1.

The first capacitor C1 is connected between the field-effect transistor M1 and the ground terminal 13. A source terminal S_{M1} of the field-effect transistor M1 is connected to the second terminal 12 and one end t3 of the first capacitor C1. A gate terminal G_{M1} of the field-effect transistor M1 is connected to the other end t4 of the first capacitor C1. The other end t4 of the first capacitor C1 is connected to the ground terminal 13.

The voltage generation circuit 10A of the first embodiment may further include a Zener diode DZ. An anode terminal t5 of the Zener diode DZ is connected to the other end t4 of the first capacitor C1. A cathode terminal t6 of the Zener diode DZ is connected to the source terminal S_{M1} of the field-effect transistor M1 and the second terminal 12.

The voltage generation circuit 10A of the first embodiment may further include a second diode D2 for backflow prevention connected between the source terminal S_{M1} of the field-effect transistor M1 and the second terminal 12. An anode terminal t9 of the second diode D2 is connected to the source terminal S_{M1}, and a cathode terminal t10 of the second diode D2 is connected to the second terminal 12.

The voltage across the semiconductor switching element 300 (drain-source voltage) is applied between the first terminal 11 of the voltage generation circuit 10A and the other end t4 of the first capacitor C1. When the semiconductor switching element 300 is repeatedly turned on and off, the drain-source voltage of the semiconductor switching element 300 changes in a pulsed manner.

As shown in FIG. 2B, the voltage generation circuit 10A may include a plurality of field-effect transistors including the field-effect transistor M1 and a plurality of capacitors including the first capacitor C1. A plurality of sets of field-effect transistors and capacitors are connected between the cathode terminal t2 of the first diode D1 and the anode terminal t5 of the Zener diode DZ. With the voltage generation circuit 10A shown in FIG. 2B, the generated voltage rises.

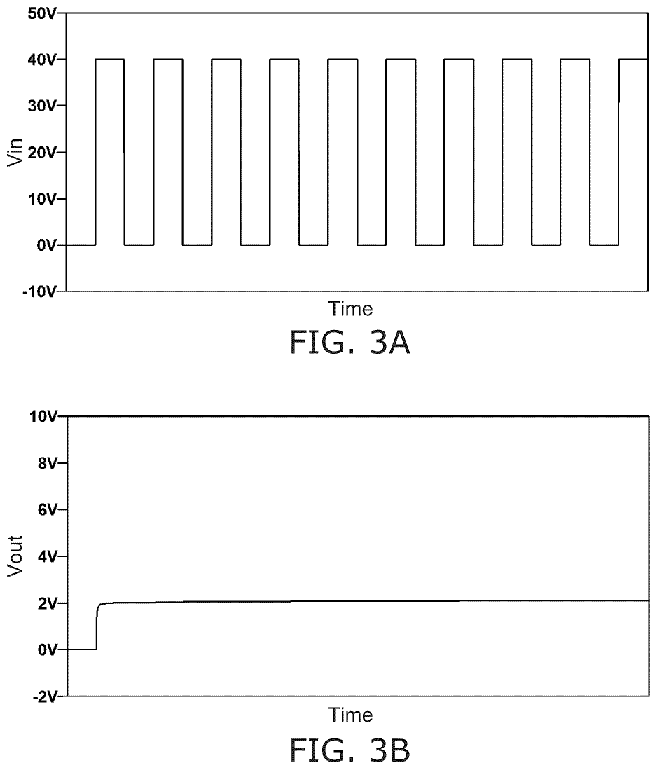

FIG. 3A shows an example of the drain-source voltage of the semiconductor switching element 300, that is, an input voltage Vin applied between the first terminal 11 of the voltage generation circuit 10A and the other end t4 of the first capacitor C1. In this example, the input voltage Vin is 40 V when the semiconductor switching element 300 is off, and the input voltage Vin is 0 V when the semiconductor switching element 300 is on.

FIG. 3B is a waveform diagram of an output voltage Vout output to the second terminal 12 when the input voltage Vin is as shown in FIG. 3A. FIG. 3A and FIG. 3B show simulation results.

When the first capacitor C1 is not charged and the potential (output voltage Vout) of the second terminal 12 is 0 V, the potential (source potential) of the source terminal S_{M1} of the field-effect transistor M1 and the potential (gate potential) of the gate terminal G_{M1} thereof are both 0 V, and the depletion-type field-effect transistor M1 is in an ON state.

A current flows from the first terminal 11 through the first diode D1 and the field-effect transistor M1 in the ON state, and the first capacitor C1 is charged. As the first capacitor C1 is charged, the source potential of the field-effect transistor M1 rises from 0 V, and the gate potential drops relative to the source potential. The threshold voltage of the field-effect transistor M1 is assumed to be −2 V. When the source potential rises to 2 V, the gate voltage of the field-effect transistor M1 (the difference between the gate potential and the source potential) reaches the threshold voltage (−2 V), the field-effect transistor M1 is turned off, and a current does not flow through the first capacitor C1 anymore. Accordingly, the voltage generation circuit 10A outputs a constant voltage (2 V) to the second terminal 12 as shown in FIG. 3B.

The first diode D1 prevents a current from flowing back to the first terminal 11 due to discharge from the first capacitor C1 when the potential of the first terminal 11 drops to 0 V.

According to the embodiment, for example, a constant voltage for the gate drive circuit 210 can be generated from the voltage across the semiconductor switching element 300 (drain-source voltage) with a simple configuration. An external power supply for the gate drive circuit 210 is not separately required. Further, when the source potential reaches the predetermined potential, the field-effect transistor M1 is turned off, and a current for charging the first capacitor C1 does not flow even when a voltage is applied between the drain and the source of the semiconductor switching element 300, which can reduce power consumption.

Even when the field-effect transistor M1 is off, the first capacitor C1 may be charged with a leakage current over a long period, and the source potential may rise more than necessary, which is a concern. According to the embodiment, when the source potential rises more than necessary and the Zener diode DZ reaches the breakdown voltage, the current can be released from the source terminal S_{M1} to the ground via the Zener diode DZ. Accordingly, the output voltage Vout can be prevented from rising.

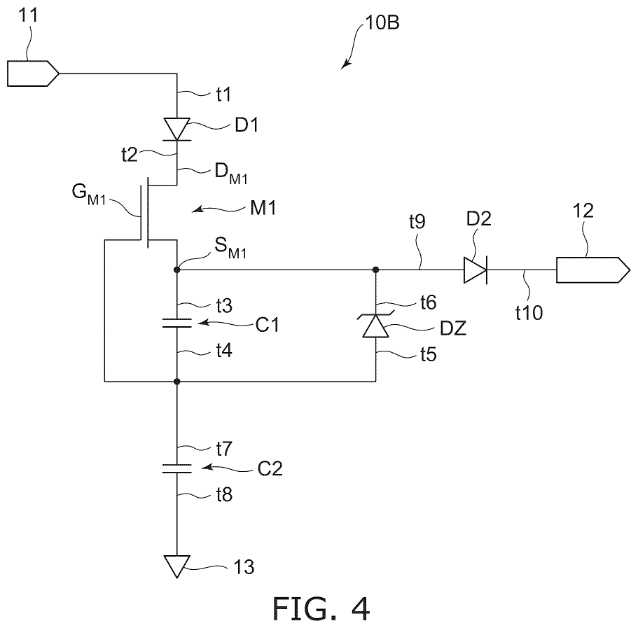

FIG. 4 is a circuit diagram of a voltage generation circuit 10B of a second embodiment.

The voltage generation circuit 10B of the second embodiment further includes a second capacitor C2 connected in series to the first capacitor C1. The gate terminal G_{M1} of the field-effect transistor M1 is connected between the first capacitor C1 and the second capacitor C2.

Also in the second embodiment, the threshold voltage Vth of the field-effect transistor M1 is assumed to be, for example, −2 V. Since the first capacitor C1 and the second capacitor C2 are connected in series, the charge stored in the first capacitor C1 and the charge stored in the second capacitor C2 are the same. For example, when the capacitance of the first capacitor C1 is assumed to be 8 nF and the capacitance of the second capacitor C2 is assumed to be 2 nF, the voltage across the second capacitor C2 is four times the voltage across the first capacitor C1. For example, when the first capacitor C1 is charged to 2 V and the field-effect transistor M1 is turned off, the second capacitor C2 is charged to 8 V. Therefore, the source potential of the field-effect transistor M1 can be made to rise to 10 V higher than −Vth=+2 V, and a constant voltage of 10 V can be output to the second terminal 12.

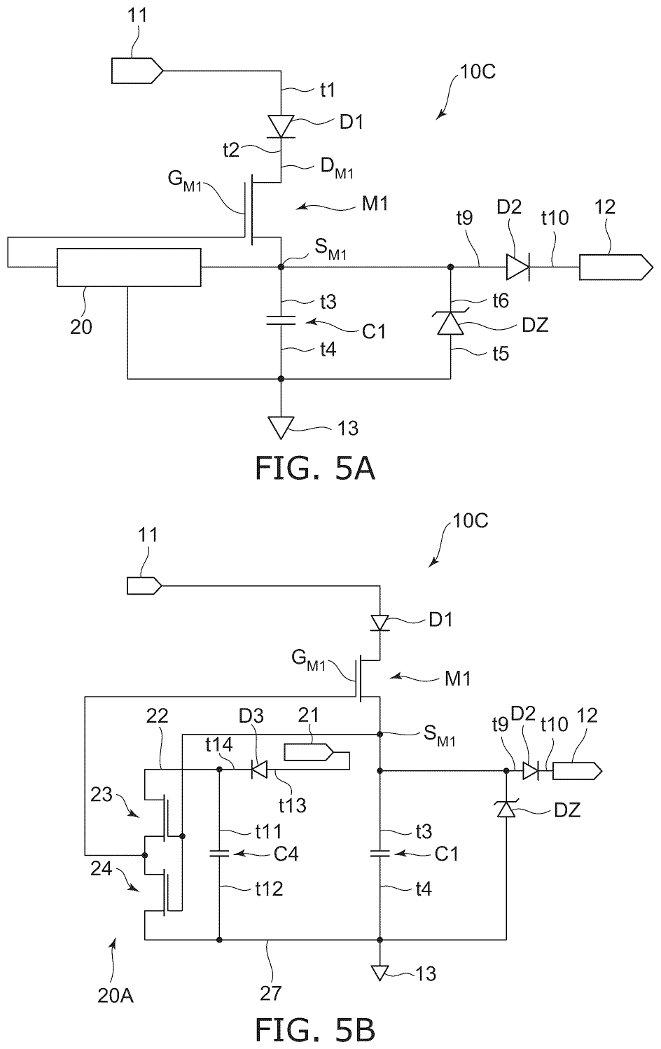

FIG. 5A is a circuit diagram of a voltage generation circuit 10C of a third embodiment.

The voltage generation circuit 10C of the third embodiment further includes a buffer circuit 20 connected between the gate terminal G_{M1} and the source terminal S_{M1} of the field-effect transistor M1. As the buffer circuit 20, for example, an inverter, a comparator, a trigger circuit, or a Schmitt trigger circuit can be used. The comparator, the trigger circuit, or the Schmitt trigger circuit can be combined with a NOT circuit.

FIG. 5B is a circuit diagram of an example of the voltage generation circuit 10C in which an inverter 20A is used as the buffer circuit 20.

The inverter 20A includes a third semiconductor element 23 and a fourth semiconductor element 24. For example, the third semiconductor element 23 is a p-type MOSFET, and the fourth semiconductor element 24 is an n-type MOSFET. The third semiconductor element 23 and the fourth semiconductor element 24 constitute a CMOS circuit.

Further, the voltage generation circuit 10C includes a third terminal 21, a third diode D3, and a fourth capacitor C4. A voltage for driving the inverter 20A is supplied from the third terminal 21 to a voltage supply line 22 of the inverter 20A.

The third diode D3 is connected between the third terminal 21 and the source terminal of the third semiconductor element 23. The anode terminal of the third diode D3 is connected to the third terminal 21, and the cathode terminal of the third diode D3 is connected to the source terminal of the third semiconductor element 23. One end t11 of the fourth capacitor C4 is connected to the voltage supply line 22 between the cathode terminal of the third diode D3 and the source terminal of the third semiconductor element 23. The other end t12 of the fourth capacitor C4 is connected to a reference potential line 27 of the inverter 20A.

The drain terminal of the third semiconductor element 23 is connected to the voltage supply line 22. The source terminal of the fourth semiconductor element 24 is connected to the reference potential line 27. The gate terminal of the third semiconductor element 23 and the gate terminal of the fourth semiconductor element 24 are connected to the source terminal S_{M1} of the field-effect transistor M1. The drain terminal of the third semiconductor element 23 and the drain terminal of the fourth semiconductor element 24 are connected to the gate terminal G_{M1} of the field-effect transistor M1.

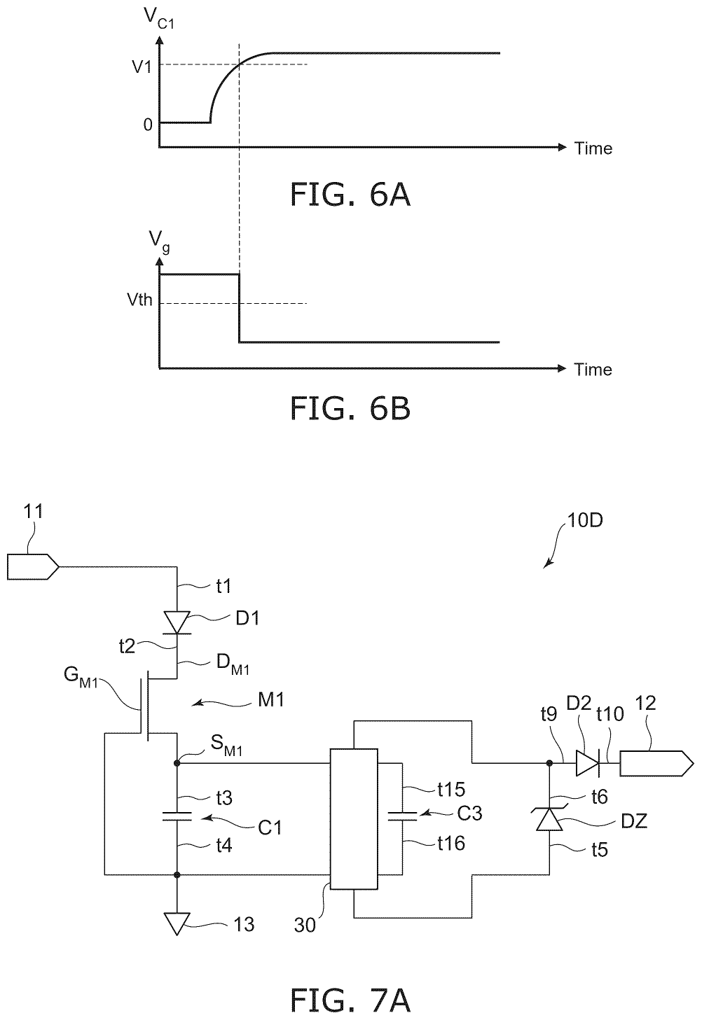

FIG. 6A is a waveform diagram of a source potential V_{C1} of the field-effect transistor M1. FIG. 6B is a waveform diagram of a gate potential Vg of the field-effect transistor M1. FIG. 6A and FIG. 6B show simulation results.

When the source potential V_{C1} is 0 V, the third semiconductor element 23 is turned on and the fourth semiconductor element 24 is turned off. Accordingly, the potential of the third terminal 21 is applied to the gate terminal G_{M1} of the field-effect transistor M1 via the third semiconductor element 23 in the ON state, and the field-effect transistor M1 enters the ON state.

When the first capacitor C1 is charged as described above, the source potential V_{C1} rises as shown in FIG. 6A. When the source potential V_{C1} exceeds a first threshold value V1, the third semiconductor element 23 is turned off and the fourth semiconductor element 24 is turned on. Accordingly, the gate potential Vg becomes 0 V. For example, the gate potential Vg becomes −2 V when viewed from the source potential V_{C1}, and the field-effect transistor M1 is turned off. Accordingly, the charging of the first capacitor C1 is stopped, and the constant voltage (for example, 2 V) is output to the second terminal 12 as described above.

MOSFETs tend to have a high resistance in the vicinity of a threshold voltage Vth, and a loss when a current flows is likely to increase. According to the embodiment, when the source potential V_{C1} of the field-effect transistor M1 exceeds the first threshold value V1 before reaching a predetermined potential (for example, 2 V), the buffer circuit 20 changes the gate potential Vg of the field-effect transistor M1 to a potential lower than the threshold voltage Vth of the field-effect transistor M1 to turn off the field-effect transistor M1. Accordingly, the period in which the current flows in the vicinity of the threshold voltage Vth of the field-effect transistor M1 can be shortened, and the loss can be reduced.

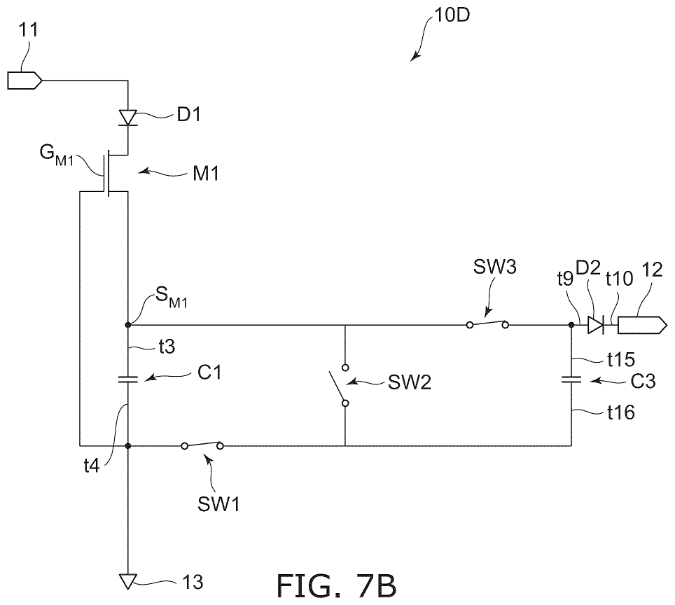

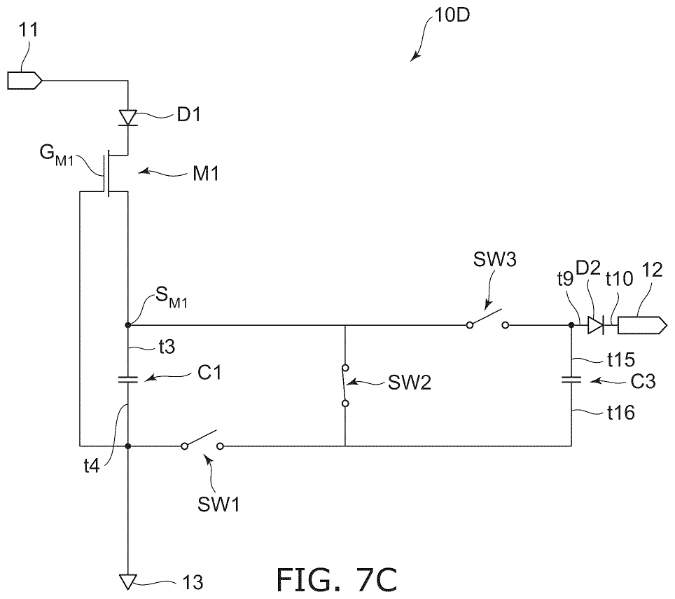

FIG. 7A, FIG. 7B, and FIG. 7C are circuit diagrams of a voltage generation circuit 10D of a fourth embodiment.

As shown in FIG. 7A, the voltage generation circuit 10D of the fourth embodiment includes a third capacitor C3 and a series-parallel switching circuit 30. In FIG. 7B and FIG. 7C, the series-parallel switching circuit 30 is illustrated as a configuration that includes three switching elements SW1 to SW3. As the switching elements SW1 to SW3, for example, semiconductor elements can be used.

The series-parallel switching circuit 30 is connected to the source terminal S_{M1} of the field-effect transistor M1, the one end t3 of the first capacitor C1, and the other end t4 of the first capacitor C1. The series-parallel switching circuit 30 is connected to the second terminal 12 and the third capacitor C3.

One end of the switching element SW3 is connected to the source terminal S_{M1} of the field-effect transistor M1. The other end of the switching element SW3 is connected to the second terminal 12 and one end t15 of the third capacitor C3.

One end of the switching element SW1 is connected to the other end t4 of the first capacitor C1. The other end of the switching element SW1 is connected to the other end t16 of the third capacitor C3.

One end of the switching element SW2 is connected to the source terminal S_{M1} of the field-effect transistor M1 and the one end of the switching element SW3. The other end of the switching element SW2 is connected to the other end of the switching element SW1 and the other end t16 of the third capacitor C3.

The series-parallel switching circuit 30 can switch between a first state (state shown in FIG. 7C) in which the first capacitor C1 and the third capacitor C3 are connected in parallel to the field-effect transistor M1 and a second state (state shown in FIG. 7B) in which the first capacitor C1 and the third capacitor C3 are connected in series to the field-effect transistor M1.

As shown in FIG. 7C, when the switching element SW2 is on and the switching element SW1 and the switching element SW3 are off, the first capacitor C1 and the third capacitor C3 are connected in parallel to the field-effect transistor M1. Accordingly, when the input voltage to the first terminal 11 (the voltage across the semiconductor switching element 300 shown in FIG. 1) is, for example, 5 V, each of the first capacitor C1 and the third capacitor C3 is charged at 5 V.

As shown in FIG. 7B, when the switching element SW1 and the switching element SW3 are on and the switching element SW2 is off, the first capacitor C1 and the third capacitor C3 are connected in series to the field-effect transistor M1. Accordingly, 10 V is output to the second terminal 12.

According to the embodiment, a voltage higher than the input voltage to the first terminal 11 can be output to the second terminal 12.

With the voltage generation circuits 10A to 10D of the respective embodiments described above, since the constant voltage is generated from the voltage across the semiconductor switching element 300 (drain-source voltage), a failure in the semiconductor switching element 300 can be detected by monitoring the output voltage from the second terminal 12.

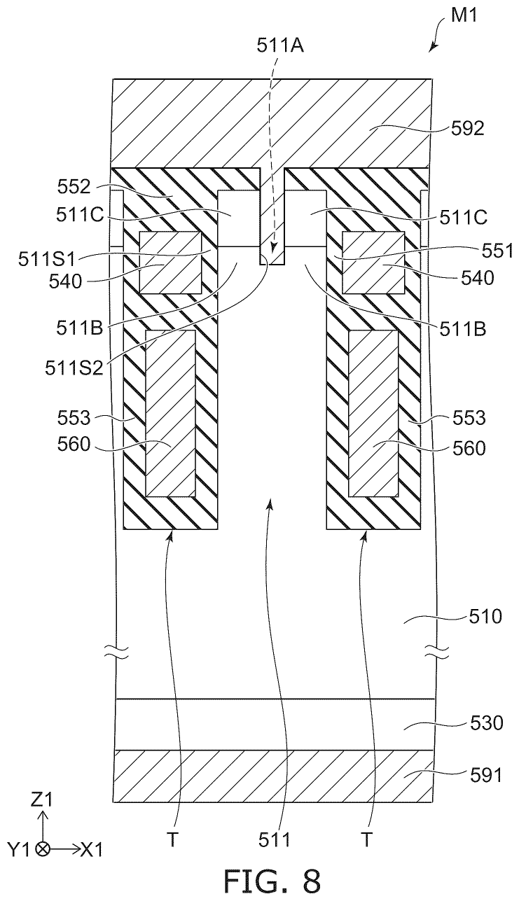

FIG. 8 is a schematic cross-sectional view of an example of the field-effect transistor M1 in the voltage generation circuits 10A to 10D of the respective embodiments described above. In FIG. 8, directions are indicated by an X1 axis, a Y1 axis, and a Z1 axis. A direction along the X1 axis is defined as a first direction X1. A direction along the Y1 axis is defined as a second direction Y1, and the second direction Y1 is orthogonal to the first direction X1. A direction along the Z1 axis is defined as a third direction Z1, and the third direction Z1 is orthogonal to the first direction X1 and the second direction Y1.

In the specification, a first conductivity type in a semiconductor layer is assumed to be the n-type, and a second conductivity type is assumed to be the p-type. Note that the first conductivity type may be the p-type, and the second conductivity type may be the n-type. The semiconductor layer is, for example, a silicon layer. Alternatively, the semiconductor layer may be, for example, a silicon carbide layer or a gallium nitride layer.

The field-effect transistor M1 includes a first electrode 591, an n-type first semiconductor layer 510 provided on the first electrode 591, a second electrode 592 provided on the first semiconductor layer 510, and a first gate electrode 540. The first electrode 591 is electrically connected to the drain terminal D_{M1} described above. The second electrode 592 is electrically connected to the source terminal S_{M1} described above. The first gate electrode 540 is electrically connected to the gate terminal G_{M1} described above.

In the ON state of the field-effect transistor M1 in which the gate voltage of the first gate electrode 540 is made higher than the threshold voltage, a current flows in the longitudinal direction (third direction Z1) between the first electrode 591 and the second electrode 592 through the first semiconductor layer 510. In the third direction Z1, a direction from the first electrode 591 toward the second electrode 592 is defined as up, upward, or above, and a direction from the second electrode 592 toward the first electrode 591 is defined as down, downward, or below.

The first semiconductor layer 510 includes a plurality of mesa portions 511 located apart from each other in the first direction X1 and extending in the second direction Y1. A trench structure portion T including the first gate electrode 540 is provided adjacent to the mesa portion 511 in the first direction X1. A plurality of the trench structure portions T are arranged in the first direction X1. Each trench structure portion T extends in the second direction Y1.

The second electrode 592 is located in a recessed portion 511A provided in an upper portion of the mesa portion 511. The recessed portion 511A and the second electrode 592 in the recessed portion 511A extend in the second direction Y1. The second electrode 592 is also provided on the trench structure portion T.

The trench structure portion T further includes an insulating layer 552 provided between the gate electrode 540 and the second electrode 592 in the third direction Z1, and a first insulating film 551 provided between the mesa portion 511 and the gate electrode 540 in the first direction X1.

The trench structure portion T may further include a field plate electrode 560 and a second insulating film 553. The field plate electrode 560 is located below the gate electrode 540. The second insulating film 553 is provided between the gate electrode 540 and the field plate electrode 560 and between the field plate electrode 560 and the first semiconductor layer 510.

A portion of the mesa portion 511 located between the trench structure portion T and the second electrode 592 (recessed portion 511A) includes a first side face 511S1 and a second side face 511S2. The first side face 511S1 faces the gate electrode 540 in the first direction X1 with the first insulating film 551 interposed therebetween. The second side face 511S2 is located opposite to the first side face 511S1 in the first direction X1. The second electrode 592 in the recessed portion 511A is in contact with the second side face 511S2.

A portion of the mesa portion 511 between the first side face 511S1 and the second side face 511S2 includes a channel portion 511B and a contact portion 511C. The channel portion 511B faces the gate electrode 540 in the first direction X1 with the first insulating film 551 interposed therebetween. The contact portion 511C is provided on the channel portion 511B. The n-type impurity concentration of the contact portion 511C is higher than the n-type impurity concentration of the channel portion 511B. The mesa portion 511 does not include a p-type semiconductor layer.

The second electrode 592 is made of a metal material. The second electrode 592 and the second side face 511S2 of the channel portion 511B form a Schottky junction. The second electrode 592 is in direct contact with the second side face 511S2 of the channel portion 511B. Alternatively, the second electrode 592 may be in contact with the second side face 511S2 of the channel portion 511B with an insulating film interposed therebetween. The second electrode 592 is in ohmic contact with the second side face 511S2 of the contact portion 511C.

The field-effect transistor M1 further includes an n-type semiconductor layer 530 provided between the first electrode 591 and the first semiconductor layer 510 and electrically connected to the first electrode 591. The n-type impurity concentration of the semiconductor layer 530 is higher than the n-type impurity concentration of the first semiconductor layer 510.

In the ON state of the field-effect transistor M1, a current flows between the first electrode 591 and the second electrode 592 via the contact portion 511C and the channel portion 511B.

In an OFF state of the field-effect transistor M1, the channel portion 511B is depleted by a depletion layer extending in the first direction X1 from the Schottky junction between the second side face 511S2 of the channel portion 511B and the second electrode 592 and a depletion layer extending in the first direction X1 from the boundary between the second side face 511S2 of the channel portion 511B and the first insulating film 551 of the trench structure portion T.

The threshold voltage of the field-effect transistor M1 depends on the width of the channel portion 511B in the first direction X1. The breakdown voltage and the threshold voltage of the field-effect transistor M1 depend on the barrier height between the metal of the second electrode 592 and the first semiconductor layer 510.

When the width of the channel portion 511B in the first direction X1 is decreased in the Schottky-junction-type field-effect transistor M1 shown in FIG. 8, the threshold voltage can be easily decreased, and the field-effect transistor M1 can be of a depletion type. In the Schottky-junction-type field-effect transistor M1, the transconductance gₘ in the vicinity of the threshold voltage can be increased. Therefore, the Schottky-junction-type field-effect transistor M1 has a small loss in the vicinity of the threshold voltage and is suitable for the voltage generation circuit described above.

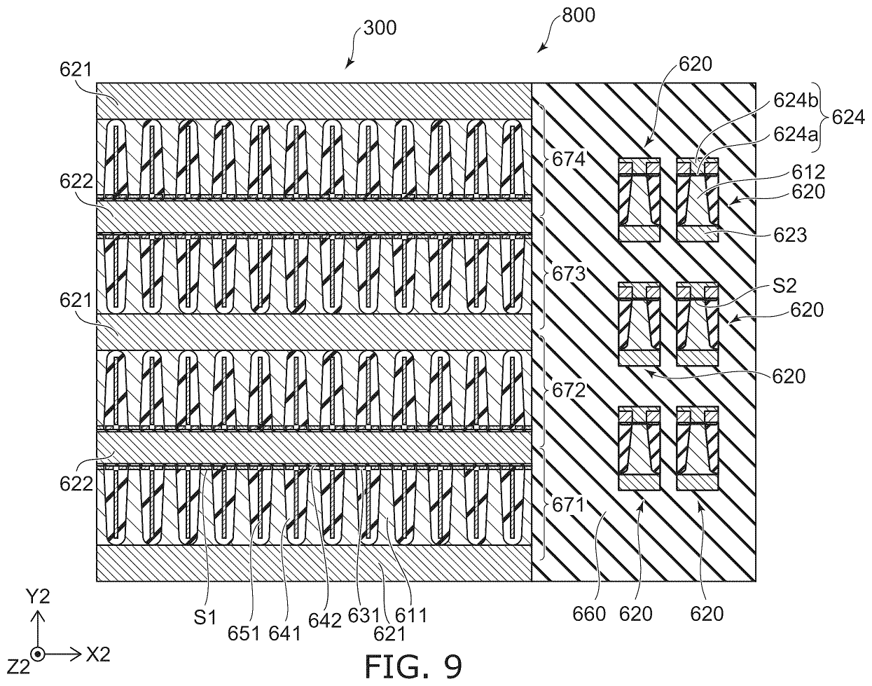

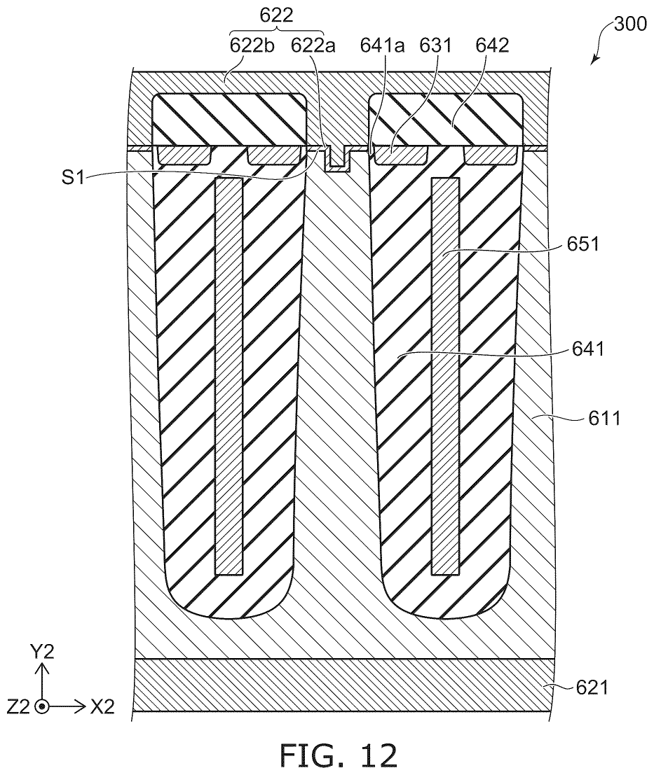

With reference to FIG. 9 to FIG. 15, a semiconductor device 800 of an embodiment will be described.

As shown in FIG. 9, the semiconductor device 800 of the embodiment includes the semiconductor switching element 300 shown in FIG. 1 described above and a control element 620. The control element 620 includes the field-effect transistor M1 in the voltage generation circuits described above and/or the semiconductor elements of the gate drive circuit 210.

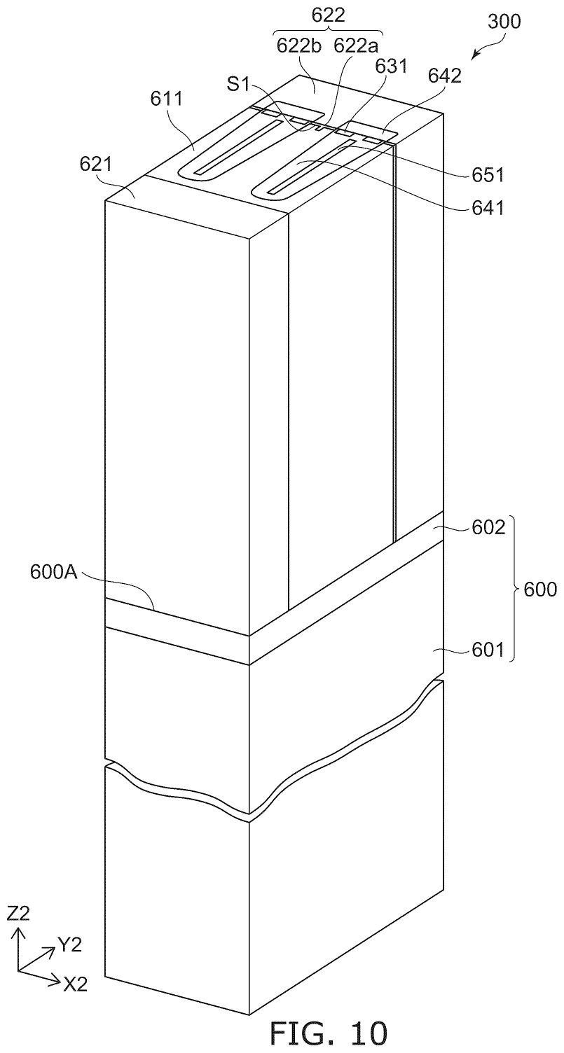

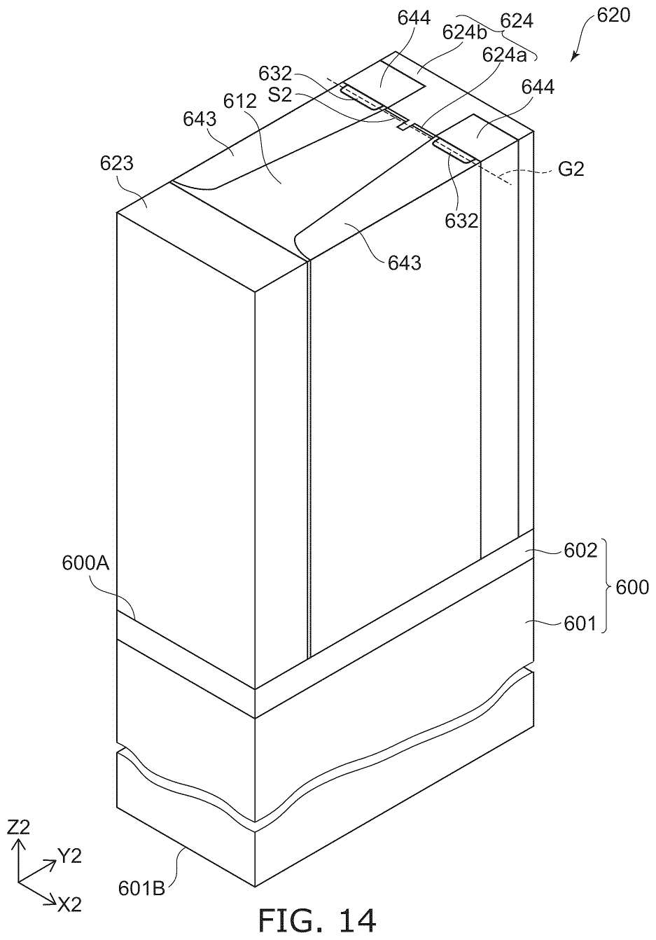

The semiconductor device 800 further includes a support 600. As shown in FIG. 10, the semiconductor switching element 300 is provided on the support 600. As shown in FIG. 14, the control element 620 is also provided on the support 600.

As shown in FIG. 10, the support 600 includes a first face 600A. One direction parallel to the first face 600A is defined as an X2-axis direction. A direction parallel to the first face 600A and perpendicular to the X2-axis direction is defined as a Y2-axis direction. A direction perpendicular to the X2-axis direction and the Y2-axis direction is defined as a Z2-axis direction. The first face 600A is perpendicular to the Z2-axis direction. For example, a direction along the Y2 axis is defined as a first direction Y2, a direction along the X2 axis is defined as a second direction X2, and a direction along the Z2 axis is defined as a third direction Z2.

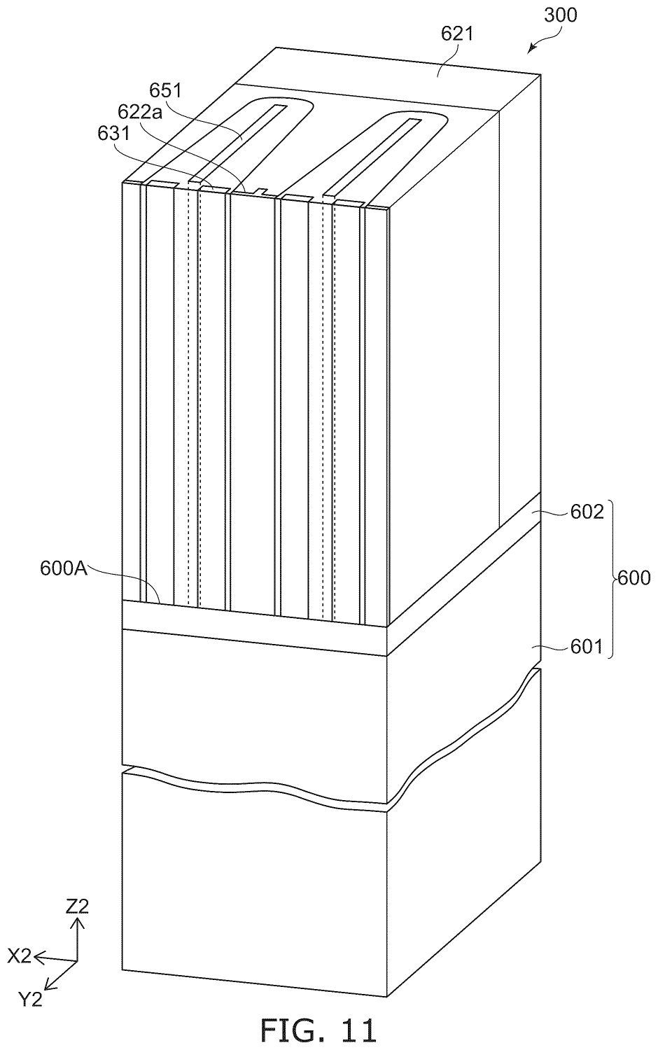

The semiconductor switching element 300 will be described with reference to FIG. 10 to FIG. 13B. FIG. 11 illustrates a state in which a second conductive portion 622b and a second insulating member 642 are removed.

The support 600 includes a substrate 601. As the substrate 601, for example, a silicon substrate can be used. The semiconductor switching element 300 includes a second semiconductor layer 611 provided on the substrate 601 in the third direction Z2. The support 600 may further include an insulating layer 602 provided between the substrate 601 and the second semiconductor layer 611 in the third direction Z2. In this example, the upper face of the insulating layer 602 is the first face 600A of the support 600. As the insulating layer 602, for example, a silicon oxide layer can be used.

The conductivity type of the second semiconductor layer 611 is the first conductivity type. The first conductivity type is one of the n-type and the p-type. The first conductivity type is assumed to be the n-type below. The second semiconductor layer 611 is, for example, a silicon layer. The second semiconductor layer 611 may be a silicon carbide layer or a gallium nitride layer.

The semiconductor switching element 300 further includes a third electrode 621 and a fourth electrode 622. The third electrode 621 is electrically connected to the drain terminal D of the semiconductor switching element 300 shown in FIG. 1. The fourth electrode 622 is electrically connected to the source terminal S of the semiconductor switching element 300 shown in FIG. 1. The third electrode 621 and the fourth electrode 622 are located apart from each other in the first direction Y2. The second semiconductor layer 611 is provided between the third electrode 621 and the fourth electrode 622 in the first direction Y2, and is electrically connected to the third electrode 621 and the fourth electrode 622. The third electrode 621, the fourth electrode 622, and the second semiconductor layer 611 extend upward in the third direction Z2 above the first face 600A. The upward is a direction from the substrate 601 toward the second semiconductor layer 611. The downward is a direction opposite to the upward. The upward and the downward are directions independent of the direction of gravity. With such a configuration, the density of the semiconductor switching element 300 on the first face 600A of the support 600 can be increased and, for example, the on-resistance per unit area can be decreased.

The third electrode 621 can include, for example, at least one selected from the group consisting of Al, Cu, Mo, W, Ta, Co, Ru, Ti, and Pt.

The fourth electrode 622 includes a first conductive portion 622a and the second conductive portion 622b. The first conductive portion 622a is in contact with the second semiconductor layer 611. The second semiconductor layer 611 and the first conductive portion 622a form a first Schottky junction S1. The first conductive portion 622a is located between the second semiconductor layer 611 and the second conductive portion 622b in the first direction Y2. The second conductive portion 622b is electrically connected to the first conductive portion 622a.

The first conductive portion 622a can include, for example, at least one selected from the group consisting of Ti, W, Mo, Ta, Zr, Al, Sn, V, Re, Os, Ir, Pt, Pd, Rh, Ru, Nb, Sr, and Hf. The second conductive portion 622b can include, for example, at least one selected from the group consisting of Al, Cu, Mo, W, Ta, Co, Ru, Ti, and Pt.

The semiconductor switching element 300 further includes a second gate electrode 631. The second gate electrode 631 is electrically connected to the gate terminal G of the semiconductor switching element 300 shown in FIG. 1. A plurality of the second gate electrodes 631 are arranged in the second direction X2. The second gate electrode 631 faces the first Schottky junction S1 in the second direction X2. As the material of the second gate electrode 631, for example, polycrystalline silicon can be used. As shown in FIG. 11, the second gate electrode 631 extends in the third direction Z2. With such a configuration, the MOS structure can be provided on the first face 600A of the support 600 at high density, and the channel area per unit area can be increased. Accordingly, for example, the on-resistance can be reduced. In the semiconductor switching element 300, since a current does not flow through the support 600, the on-resistance does not increase even if the thickness of the support 600 in the third direction Z2 is increased in order to increase the mechanical strength.

The n-type impurity concentration of a region that is in contact with the third electrode 621 in the second semiconductor layer 611 may be made higher than the n-type impurity concentration of the other region. Accordingly, the contact resistance between the third electrode 621 and the second semiconductor layer 611 can be reduced.

The thickness (distance in the first direction Y2) of the Schottky barrier in the first Schottky junction S1 can be controlled with the potential of the second gate electrode 631. When the Schottky barrier is thick, a current does not substantially flow between the fourth electrode 622 and the second semiconductor layer 611. Accordingly, the OFF state is obtained. In the OFF state, a depletion layer spreads from the first Schottky junction S1 into the second semiconductor layer 611, and the breakdown voltage can be maintained.

When the potential of the second gate electrode 631 is controlled by the gate driver 200 described above, the Schottky barrier becomes thin and, for example, a tunnel current flows between the fourth electrode 622 and the second semiconductor layer 611. When the tunnel current flows, the ON state is obtained.

The semiconductor switching element 300 can further include a field plate electrode 651, a first insulating member 641, and the second insulating member 642.

The field plate electrode 651 is provided in a trench formed in the second semiconductor layer 611, and extends in the first direction Y2 and the third direction Z2. The field plate electrode 651 is electrically connected to, for example, the fourth electrode 622. An electric field applied to the second semiconductor layer 611 in the first direction Y2 can be relaxed by the field plate electrode 651, and the breakdown voltage can be increased. As the material of the field plate electrode 651, for example, polycrystalline silicon can be used.

The first insulating member 641 is provided between the second gate electrode 631 and the second semiconductor layer 611, between the field plate electrode 651 and the second semiconductor layer 611, between the second gate electrode 631 and the field plate electrode 651, and between the second gate electrodes 631 adjacent to each other in the second direction X2, and extends in the third direction Z2. The first insulating member 641 includes a first gate insulating portion 641a. The first gate insulating portion 641a is provided between the second gate electrode 631 and the second semiconductor layer 611, between the second gate electrode 631 and the first Schottky junction S1, and between the second gate electrode 631 and the first conductive portion 622a. The second gate electrode 631 faces the first Schottky junction S1 in the second direction X2 with the first gate insulating portion 641a interposed therebetween. As the material of the first insulating member 641, for example, silicon oxide can be used.

The second insulating member 642 is provided between the second gate electrode 631 and the second conductive portion 622b and between the first insulating member 641 and the second conductive portion 622b, and extends in the third direction Z2. As the material of the second insulating member 642, for example, silicon oxide can be used.

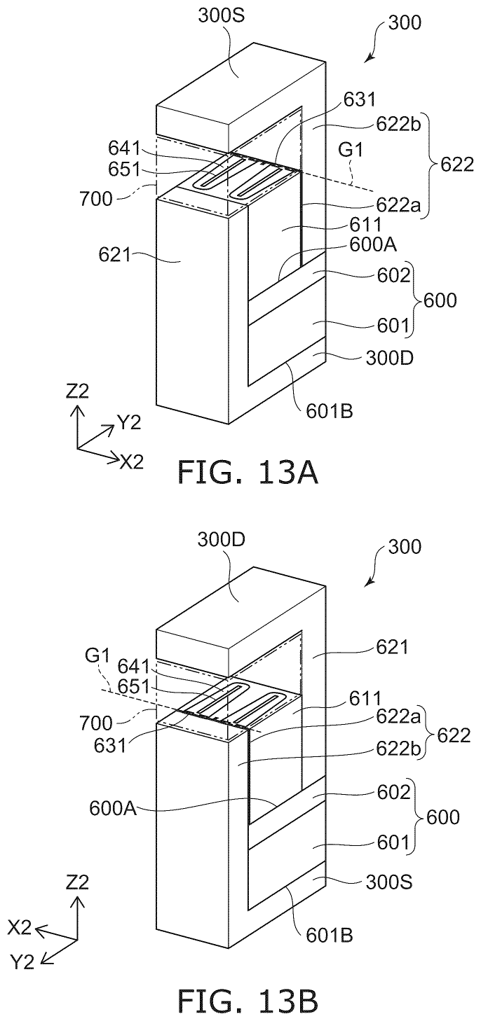

As shown in FIG. 13A, the substrate 601 includes a second face 601B located opposite to the first face 600A in the third direction Z2. An interlayer insulating layer (illustrated in a two-dot chain line) 700 is provided above and in contact with the second semiconductor layer 611. On the second face 601B of the substrate 601, a first wiring portion 300D electrically connected to the third electrode 621 is provided. The first wiring portion 300D is electrically connected to the drain terminal D of the semiconductor switching element 300. A part of the first wiring portion 300D is located below the semiconductor device 800 and is exposed. A part of the first wiring portion 300D extends parallel to the first direction Y2 and the second direction X2. The substrate 601 is located between the first wiring portion 300D and the second semiconductor layer 611.

In the third direction Z2, a second wiring portion 300S can be provided above the second semiconductor layer 611, above the second gate electrode 631, and above the field plate electrode 651 with the interlayer insulating layer interposed therebetween. The second wiring portion 300S is electrically connected to the second conductive portion 622b of the fourth electrode 622. The second wiring portion 300S is electrically connected to the source terminal S of the semiconductor switching element 300. A part of the second wiring portion 300S is located above the semiconductor device 800 and is exposed. A part of the second wiring portion 300S extends parallel to the first direction Y2 and the second direction X2. The interlayer insulating layer 700 is located between a part of the second wiring portion 300S and the second semiconductor layer 611.

On the plurality of second gate electrodes 631 arranged in the second direction X2, a first gate line G1 extending in the second direction X2 is provided, and the plurality of second gate electrodes 631 can be electrically connected to the first gate line G1. The first gate line G1 is electrically connected to the gate terminal G of the semiconductor switching element 300. The first gate line G1 is located in the interlayer insulating layer 700. The first gate line G1 may be located above the semiconductor device 800 and exposed. For example, the semiconductor device 800 can be placed on an electrode of an external circuit with the second wiring portion 300S being in contact with the electrode. A wiring portion other than the second wiring portion 300S included in the semiconductor device 800 is exposed from above the semiconductor device 800 and is connected to the external circuit by, for example, wire bonding. In the semiconductor device 800, an exposed area of the first wiring portion 300D and the second wiring portion 300S, which are main current paths, that is, a contact area with the external circuit, can be increased.

Alternatively, as shown in FIG. 13B, the second wiring portion 300S electrically connected to the second conductive portion 622b of the fourth electrode 622 may be provided on the second face 601B of the substrate 601. In the third direction Z2, the first wiring portion 300D electrically connected to the third electrode 621 can be provided above the second semiconductor layer 611, above the second gate electrode 631, and above the field plate electrode 651 with the interlayer insulating layer interposed therebetween. A part of the first wiring portion 300D is located above the semiconductor device 800 and is exposed. A part of the first wiring portion 300D extends parallel to the first direction Y2 and the second direction X2. A part of the second wiring portion 300S is located below the semiconductor device 800 and is exposed. A part of the second wiring portion 300S extends parallel to the first direction Y2 and the second direction X2.

As shown in FIG. 9, the area of the region in which the semiconductor switching element 300 is provided is larger than the area of the region in which the control element 620 is provided. In the region of the semiconductor device 800 in which the semiconductor switching element 300 is provided, a plurality of cell groups (first to fourth cell groups 671 to 674) are provided. The cell group is a group of cells, of the semiconductor switching element 300, sharing the second semiconductor layer 611. In the first direction Y2, the second cell group 672 is between the first cell group 671 and the fourth cell group 674, and the third cell group 673 is between the second cell group 672 and the fourth cell group 674. In each cell group, a plurality of the structures shown in FIG. 10 to FIG. 12 described above are repeatedly arranged in the second direction X2.

The orientation from the third electrode 621 of the first cell group 671 to the fourth electrode 622 of the first cell group 671 is opposite to the orientation from the third electrode 621 of the second cell group 672 to the fourth electrode 622 of the second cell group 672. The orientation from the third electrode 621 of the third cell group 673 to the fourth electrode 622 of the third cell group 673 is opposite to the orientation from the third electrode 621 of the fourth cell group 674 to the fourth electrode 622 of the fourth cell group 674. The orientation from the third electrode 621 of the first cell group 671 to the fourth electrode 622 of the first cell group 671 is the same as the orientation from the third electrode 621 of the third cell group 673 to the fourth electrode 622 of the third cell group 673. The orientation from the third electrode 621 of the second cell group 672 to the fourth electrode 622 of the second cell group 672 is the same as the orientation from the third electrode 621 of the fourth cell group 674 to the fourth electrode 622 of the fourth cell group 674.

The third electrode 621 is shared by the second cell group 672 and the third cell group 673. The fourth electrode 622 is shared by the first cell group 671 and the second cell group 672. The fourth electrode 622 is shared by the third cell group 673 and the fourth cell group 674.

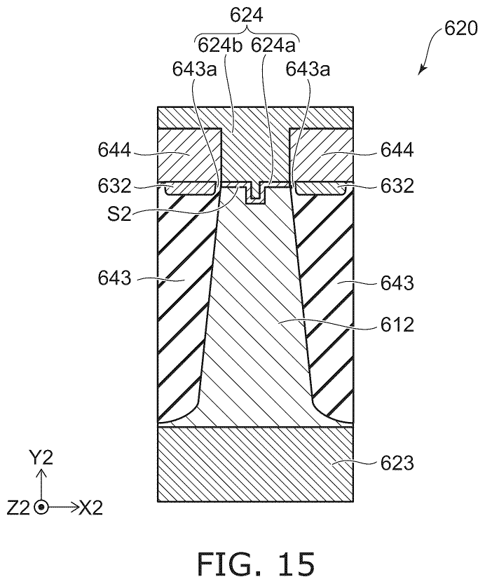

The control element 620 will now be described with reference to FIG. 14 and FIG. 15.

For example, the control element 620 is provided on the same substrate 601 on which the semiconductor switching element 300 is provided. The control element 620 is located apart from the semiconductor switching element 300 in the X-Y plane. The control element 620 includes a third semiconductor layer 612 provided on the substrate 601 in the third direction Z2. The conductivity type of the third semiconductor layer 612 is the first conductivity type. The material of the third semiconductor layer 612 can be the same as the material of the second semiconductor layer 611 of the semiconductor switching element 300.

The control element 620 further includes a fifth electrode 623 and a sixth electrode 624. The fifth electrode 623 and the sixth electrode 624 are located apart from each other in one direction on the X-Y plane, for example, in the first direction Y2. The third semiconductor layer 612 is provided between the fifth electrode 623 and the sixth electrode 624 in the first direction Y2, and is electrically connected to the fifth electrode 623 and the sixth electrode 624. The fifth electrode 623, the sixth electrode 624, and the third semiconductor layer 612 extend upward in the third direction Z2 above the first face 600A of the support 600.

The sixth electrode 624 includes a third conductive portion 624a and a fourth conductive portion 624b. The third conductive portion 624a is in contact with the third semiconductor layer 612. The third semiconductor layer 612 and the third conductive portion 624a form a second Schottky junction S2. The third conductive portion 624a is located between the third semiconductor layer 612 and the fourth conductive portion 624b in the first direction Y2. The fourth conductive portion 624b is electrically connected to the third conductive portion 624a.

The material of the fifth electrode 623 can be the same as the material of the third electrode 621 of the semiconductor switching element 300. The material of the third conductive portion 624a can be the same as the material of the first conductive portion 622a of the semiconductor switching element 300. The material of the fourth conductive portion 624b can be the same as the material of the second conductive portion 622b of the semiconductor switching element 300.

The control element 620 further includes a third gate electrode 632. A plurality of the third gate electrodes 632 are arranged in one direction on the X-Y plane, for example, in the second direction X2. The third gate electrode 632 faces the second Schottky junction S2 in the second direction X2. The third gate electrode 632 extends in the third direction Z2. The material of the third gate electrode 632 can be the same as the material of the second gate electrode 631 of the semiconductor switching element 300.

The thickness (distance in the first direction Y2) of the Schottky barrier in the second Schottky junction S2 can be controlled with the potential of the third gate electrode 632. When the Schottky barrier is thick, a current does not substantially flow between the sixth electrode 624 and the third semiconductor layer 612. Accordingly, the OFF state is obtained. When the potential of the third gate electrode 632 is controlled, the Schottky barrier becomes thin and, for example, a tunnel current flows between the sixth electrode 624 and the third semiconductor layer 612. When the tunnel current flows, the ON state is obtained.

The control element 620 can further include a third insulating member 643 and a fourth insulating member 644.

The third insulating member 643 is provided between the third gate electrode 632 and the third semiconductor layer 612, and extends in the third direction Z2. As shown in FIG. 15, the third insulating member 643 includes a second gate insulating portion 643a. The second gate insulating portion 643a is provided between the third gate electrode 632 and the third semiconductor layer 612, between the third gate electrode 632 and the second Schottky junction S2, and between the third gate electrode 632 and the third conductive portion 624a. The third gate electrode 632 faces the second Schottky junction S2 in the second direction X2 with the second gate insulating portion 643a interposed therebetween. The material of the third insulating member 643 can be the same as the material of the first insulating member 641 of the semiconductor switching element 300.

The fourth insulating member 644 is provided between the third gate electrode 632 and the fourth conductive portion 624b and between the third insulating member 643 and the fourth conductive portion 624b, and extends in the third direction Z2. The material of the fourth insulating member 644 can be the same as the material of the second insulating member 642 of the semiconductor switching element 300.

When the control element 620 is the field-effect transistor M1 described above, the fifth electrode 623 of the control element 620 is electrically connected to the drain terminal D_{M1} of the field-effect transistor M1, and the sixth electrode 624 of the control element 620 is electrically connected to the source terminal S_{M1} of the field-effect transistor M1.

When the control element 620 is the first semiconductor element 211 and the second semiconductor element 212 of the gate drive circuit 210, the fifth electrode 623 is electrically connected to the drain terminals of the first semiconductor element 211 and the second semiconductor element 212, and the sixth electrode 624 is electrically connected to the source terminals of the first semiconductor element 211 and the second semiconductor element 212.

As shown in FIG. 14, the third gate electrode 632 of the control element 620 can be electrically connected to a second gate line G2 provided on the third gate electrode 632 and extending in the second direction X2. When the control element 620 is the field-effect transistor M1, the second gate line G2 is electrically connected to the gate terminal G_{M1} of the field-effect transistor M1. An interlayer insulating layer is provided on the third semiconductor layer 612, and the second gate line G2 is provided in the interlayer insulating layer.

When the control element 620 is the first semiconductor element 211 and the second semiconductor element 212 of the gate drive circuit 210, the second gate line G2 is electrically connected to the gate terminals of the first semiconductor element 211 and the second semiconductor element 212.

According to the embodiment, the semiconductor switching element 300 and the control element 620 can be formed in the same process by only changing, for the semiconductor switching element 300 and the control element 620, a mask pattern for film formation or etching for forming each component in the semiconductor switching element 300 and the control element 620. For example, the second semiconductor layer 611 and the third semiconductor layer 612 can be formed on the same substrate 601, and the semiconductor switching element 300 and the control element 620 can be directly configured as one chip. Accordingly, a power semiconductor device into which the control element 620 is built can be formed as one chip at low cost. When the semiconductor switching element 300 and the control element 620 are formed as one chip, the parasitic inductance of the wiring electrically connecting the semiconductor switching element 300 and the control element 620 can be reduced.

As shown in FIG. 9, a fifth insulating member 660 can be provided between the semiconductor switching element 300 and the control element 620 on the substrate 601. The fifth insulating member 660 can also be provided between a plurality of the control elements 620. As the material of the fifth insulating member 660, for example, silicon oxide can be used.

Alternatively, the second semiconductor layer 611 and the third semiconductor layer 612 may be formed on the same substrate 601, and thereafter, divided into a chip of the semiconductor switching element 300 and a chip of the control element 620. In this case, the chip of the semiconductor switching element 300 and the chip of the control element 620 can be mounted on the same circuit board and packaged.

The voltage applied between the third electrode 621 and the fourth electrode 622 of the semiconductor switching element 300 is higher than the voltage applied between the fifth electrode 623 and the sixth electrode 624 of the control element 620. Therefore, in order to increase the breakdown voltage of the semiconductor switching element 300, the thickness of the second semiconductor layer 611 of the semiconductor switching element 300 in the first direction Y2 is preferably larger than the thickness of the third semiconductor layer 612 of the control element 620 in the first direction Y2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A voltage generation circuit comprising:
a first terminal;
a second terminal;
a field-effect transistor of a depletion type;
a first diode connected between the first terminal and the field-effect transistor; and
a first capacitor connected between the field-effect transistor and ground,
an anode terminal of the first diode being connected to the first terminal, a cathode terminal of the first diode being connected to a drain terminal of the field-effect transistor,
a source terminal of the field-effect transistor being connected to the second terminal and one end of the first capacitor,
a gate terminal of the field-effect transistor being connected to another end of the first capacitor.

2. The voltage generation circuit according to claim 1, further comprising:
a Zener diode,
an anode terminal of the Zener diode being connected to the other end of the first capacitor, a cathode terminal of the Zener diode being connected to the source terminal of the field-effect transistor and the second terminal.

3. The voltage generation circuit according to claim 1, further comprising:
a second capacitor connected in series to the first capacitor,
the gate terminal of the field-effect transistor being connected between the first capacitor and the second capacitor.

4. The voltage generation circuit according to claim 1, further comprising:
a buffer circuit connected between the gate terminal and the source terminal of the field-effect transistor,
the buffer circuit being configured to, when a potential of the source terminal exceeds a first threshold value, change a potential of the gate terminal to a potential lower than a threshold voltage of the field-effect transistor.

5. The voltage generation circuit according to claim 1, further comprising:
a third capacitor connected to the second terminal; and
a series-parallel switching circuit capable of switching between a first state in which the first capacitor and the third capacitor are connected in parallel to the field-effect transistor and a second state in which the first capacitor and the third capacitor are connected in series to the field-effect transistor.

6. The voltage generation circuit according to claim 1, wherein
the field-effect transistor includes
a first electrode,
a first semiconductor layer of a first conductivity type provided on the first electrode, the first semiconductor layer including a mesa portion,
a second electrode located in a recessed portion provided in an upper portion of the mesa portion,
a first gate electrode adjacent to the mesa portion in a first direction, and
an insulating film provided between the mesa portion and the first gate electrode, and
the mesa portion includes
a first side face facing the first gate electrode in the first direction with the insulating film interposed therebetween, and
a second side face located opposite to the first side face in the first direction, the second electrode being in contact with the second side face.

7. A gate driver comprising:
a gate drive circuit; and
a voltage generation circuit configured to supply a voltage to the gate drive circuit,
the voltage generation circuit including
a first terminal,
a second terminal,
a field-effect transistor of a depletion type,
a first diode connected between the first terminal and the field-effect transistor, and
a first capacitor connected between the field-effect transistor and ground,
an anode terminal of the first diode being connected to the first terminal, a cathode terminal of the first diode being connected to a drain terminal of the field-effect transistor,
a source terminal of the field-effect transistor being connected to the second terminal and one end of the first capacitor,
a gate terminal of the field-effect transistor being connected to another end of the first capacitor,
the second terminal of the voltage generation circuit being connected to the gate drive circuit.

8. The gate driver according to claim 7, wherein
the voltage generation circuit further includes a Zener diode, and
an anode terminal of the Zener diode is connected to the other end of the first capacitor, and a cathode terminal of the Zener diode is connected to the source terminal of the field-effect transistor and the second terminal.

9. The gate driver according to claim 7, wherein
the voltage generation circuit further includes a second capacitor connected in series to the first capacitor, and
the gate terminal of the field-effect transistor is connected between the first capacitor and the second capacitor.

10. The gate driver according to claim 7, wherein
the voltage generation circuit further includes a buffer circuit connected between the gate terminal and the source terminal of the field-effect transistor, and
the buffer circuit is configured to, when a potential of the source terminal exceeds a first threshold value, change a potential of the gate terminal to a potential lower than a threshold voltage of the field-effect transistor.

11. The gate driver according to claim 7, wherein
the voltage generation circuit further includes
a third capacitor connected to the second terminal, and
a series-parallel switching circuit capable of switching between a first state in which the first capacitor and the third capacitor are connected in parallel to the field-effect transistor and a second state in which the first capacitor and the third capacitor are connected in series to the field-effect transistor.

12. A semiconductor module comprising:
the gate driver according to claim 7; and
a semiconductor switching element,
a voltage across the semiconductor switching element being applied between the first terminal of the voltage generation circuit and the other end of the first capacitor,
an output terminal of the gate drive circuit being connected to a gate terminal of the semiconductor switching element.

13. The semiconductor module according to claim 12, wherein
the semiconductor switching element and the field-effect transistor of the voltage generation circuit are provided on a support including a first face,
the semiconductor switching element includes
a third electrode,
a fourth electrode located apart from the third electrode in a second direction along the first face,
a second semiconductor layer provided between the third electrode and the fourth electrode in the second direction and forming a first Schottky junction with the fourth electrode, and
a second gate electrode facing the first Schottky junction in a third direction along the first face, the third direction intersecting with the second direction, and
the field-effect transistor includes
a fifth electrode,
a sixth electrode located apart from the fifth electrode in the second direction,
a third semiconductor layer provided between the fifth electrode and the sixth electrode in the second direction and forming a second Schottky junction with the sixth electrode, and
a third gate electrode facing the second Schottky junction in the third direction.
